(19) United States
(12) Patent Application Publication
(10) Pub. No.: US 2020/0082902 A1
(43) Pub. Date: Mar. 12, 2020

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Junji TAKAHASHI, Yokohama Kanagawa (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 16/354,099

(22) Filed: Mar. 14, 2019

(30) Foreign Application Priority Data
Sep. 6, 2018 (JP) 2018-167253

(51) Int. Cl. G11C 29/00; G11C 29/56; G11C 29/30; G11C 29/20; G11C 29/44

(52) U.S. Cl. CPC G11C 29/70; G11C 29/56008; G11C 2029/5602; G11C 29/20; G11C 29/44; G11C 29/30

(57) ABSTRACT

According to one embodiment, there is provided a semiconductor device including a memory, an interface circuit, and a built-in self-test circuit. The memory includes a plurality of memory cells. The interface circuit is connected to the memory cell. The built-in self-test circuit is connected to the interface circuit and is accessible to the memory via the interface circuit. The built-in self-test circuit includes a test circuit and an analysis circuit. The analysis circuit is arranged on an output side of the test circuit and has a bit counter and a holding circuit.

### CROSS-REFERENCE TO RELATED APPLICATIONS

This application is based upon and claims the benefit of priority from Japanese Patent Application No. 2018-167253, filed on Sep. 6, 2018; the entire contents of which are incorporated herein by reference.

### FIELD

Embodiments described herein relate generally to a semiconductor device.

### BACKGROUND

In a semiconductor device such as a memory including a plurality of memory cells, a test as to whether the memory operates properly in a test process is performed. In such a test process, it is desired to efficiently test the memory.

### BRIEF DESCRIPTION OF THE DRAWINGS

FIG. 1 is a diagram illustrating a configuration of a semiconductor device according to an embodiment;

FIGS. 2A and 2B are views schematically illustrating physical configurations of a memory cell array according to the embodiment;

FIGS. 3A to 3F are views schematically illustrating data structures of failure tendency information according to the embodiment;

FIG. 4 is a diagram illustrating a configuration of a semiconductor device according to a modification of the embodiment; and

FIGS. 5A and 5B are views schematically illustrating physical configurations of a memory cell array and a redundancy repair area according to the modification of the embodiment.

### DETAILED DESCRIPTION

In general, according to one embodiment, there is provided a semiconductor device including a memory, an interface circuit, and a built-in self-test circuit. The memory includes a plurality of memory cells. The interface circuit is connected to the memory cell. The built-in self-test circuit is connected to the interface circuit and is accessible to the memory via the interface circuit. The built-in self-test circuit includes a test circuit and an analysis circuit. The analysis circuit is arranged on an output side of the test circuit and has a bit counter and a holding circuit.

Exemplary embodiments of a semiconductor device will be explained below in detail with reference to the accompanying drawings. The present invention is not limited to the following embodiments.

### Embodiment

A memory including a plurality of memory cells is mounted on the semiconductor device according to the embodiment, and the memory is tested when a failure occurs or when a product is shipped from a factory.

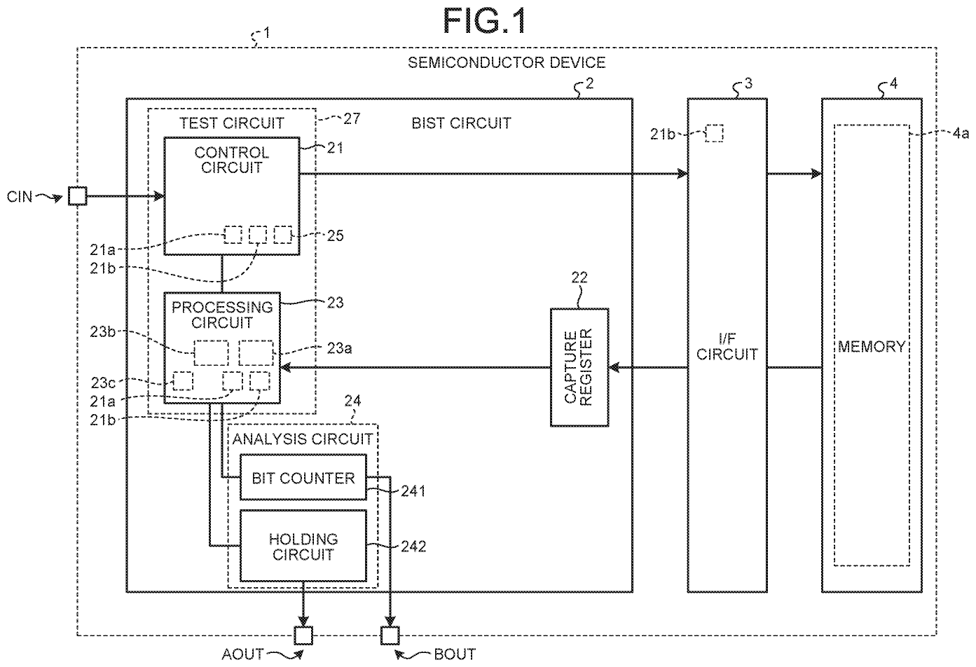

Specifically, the semiconductor device 1 can be configured as illustrated in FIG. 1. FIG. 1 is a diagram illustrating a configuration of a semiconductor device 1.

The semiconductor device 1 includes a self-test (BIST) circuit 2, an interface (I/F) circuit 3, and a memory 4. The memory 4 has a memory cell array 4a, and the memory cell array 4a includes a plurality of memory cells. The memory 4 and the I/F circuit 3, and the I/F circuit 3 and the BIST circuit 2 are electrically connected to each other.

The BIST circuit 2 is disposed on the opposite side of the memory 4 with the I/F circuit 3 interposed therebetween and can access the memory 4. With this BIST circuit, it is possible to test the memory 4 and to identify which memory cell among the plurality of memory cells is a failure bit.

Incidentally, the arrangement of the memory 4, the I/F circuit 3, and the BIST circuit 2 is not necessarily limited to those illustrated in the drawings.

The BIST circuit 2 can be electrically connected to an input terminal CIN and can be electrically connected to each of output terminals AOUT and BOUT. For example, the BIST circuit 2 can acquire information to be used for the test of the memory 4 via the input terminal CIN.

The BIST circuit 2 includes a test circuit 27 configured to test the memory 4 and an analysis circuit 24 (to be described later) which performs analysis based on a test result from the test circuit 27 and outputs an analysis result to the outside. The test circuit 27 includes a control circuit 21 configured to control the test and a processing circuit 23 configured to process the test result. The control circuit 21 can acquire a test data pattern from the outside (for example, a host) via the input terminal CIN. Alternatively, the control circuit 21 may include a pseudo random pattern generator (PRPG) (not illustrated) inside the circuit such that the test data pattern is generated using the pseudo random pattern generator.

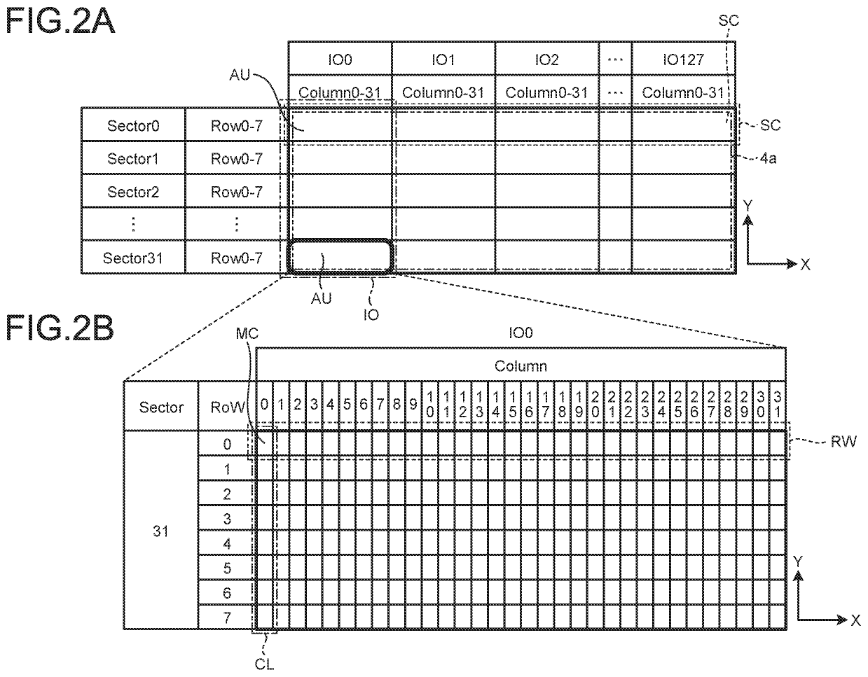

In addition, the control circuit 21 can acquire and hold management information 25 generated at the time of designing the memory 4 in advance via the input terminal CIN. With the management information 25, it is possible to hierarchically define physical positions of a two-dimensional array of the plurality of memory cells MC in the memory cell array 4a as illustrated in FIGS. 2A and 2B. FIGS. 2A and 2B are views schematically illustrating physical configurations of the memory cell array 4a. FIG. 2A is the view illustrating a schematic configuration of the memory cell array 4a, and FIG. 2B is the view illustrating a partial configuration of the memory cell array 4a in detail.

In FIGS. 2A and 2B, two array directions of the two-dimensional array are referred to as an X direction and a Y direction for the sake of convenience. In the memory cell array 4a, array units AU indicated by squares in FIG. 2A are arrayed along the X direction to constitute one sector SC. The plurality of sectors SC (32 in FIG. 2A) in the Y direction is arrayed to constitute the memory cell array 4a. The sector SC can be determined as an access unit when the memory 4 is accessed from the outside (for example, a host) during an actual operation so that write/read of data is performed.

In the memory cell array 4a, the array units AU indicated by squares in FIG. 2A are arrayed along the Y direction to constitute one I/O unit IO. The plurality of I/O units IO (127 in FIG. 2A) is arrayed in the X direction to constitute the memory cell array 4a.

In each of the array units AU, the memory cells MC indicated by squares in FIG. 2B are arrayed along the X direction to constitute one row RW. The plurality of rows RW (eight in FIG. 2A) is arrayed in the Y direction to constitute the array unit AU.

In the array unit AU, the memory cells MC indicated by squares in FIG. 2B are arrayed along the Y direction to constitute one column CL. The plurality of columns CL (31 in FIG. 2A) is arrayed in the X direction to constitute the array unit AU.

In addition, the BIST circuit 2 performs a test on the memory 4 configured as above and generates failure tendency information according to a result of the test. That is, the control circuit 21 can hierarchically manage the two-dimensional physical array of the plurality of memory cells MC in the memory cell array 4a as illustrated in FIG. 2 using the management information 25. The control circuit 21 can assign one-dimensional logical address to a physical position (two-dimensional physical position) in the two-dimensional array of the plurality of memory cells MC obtained from the management information 25 and generate an assignment result as address assignment information 21b. The address assignment information 21b is associated with a logical address (one-dimensional information, for example, an integer counted up sequentially from zero) and a two-dimensional physical position of the memory cell MC (a set of two-dimensional information, for example, a sector number, a row number, an IO number, and a column number).

The control circuit 21 supplies a test data pattern and the address assignment information 21b to the I/F circuit 3. As a result, the I/F circuit 3 can write the test data pattern at the physical position corresponding to the logical address in the memory cell array 4a of the memory 4 in accordance with the address assignment information 21b. In addition, the control circuit 21 generates data, which is the same as the test data pattern, as expected value data 21a and supplies the expected value data 21a and the address assignment information 21b to the processing circuit 23.

The BIST circuit 2 has a capture register 22. The capture register 22 captures data read from the memory cell array 4a of the memory 4 in the order of one-dimensional logical address at a predetermined timing and supplies the captured data to the processing circuit 23.

The processing circuit 23 includes a comparison circuit 23a, a multiple input signature register (MISR) 23b, and an address counter 23c. The address counter 23c counts up such a count value whenever a value (capture value) captured by the capture register 22 is supplied. The count value of the address counter 23c indicates the order in which captured values have been captured, that is, the one-dimensional logical addresses. The comparison circuit 23a compares the captured value with a corresponding value in the expected value data 21a, stores a bit value “0” indicating absence of a failure in the multiple input signature register 23b as a test result if the values coincide with each other, and stores a bit value “1” indicating presence of a failure in the multiple input signature register 23b as a comparison result if the values do not coincide with each other.

The multiple input signature register 23b can store test results while converting the captured orders (one-dimensional logical addresses) to two-dimensional physical positions of the plurality of memory cells MC using count values of the address counter 23c and the address assignment information 21b. At this time, the multiple input signature register 23b takes, compresses, and stores OR (logical sum) of physical positions (a sector, an IO, a row, and a column) in the hierarchy as illustrated in FIG. 2A.

The BIST circuit 2 has the analysis circuit 24. The analysis circuit 24 is disposed on an output side of the test circuit 27 and is disposed on an output side of the processing circuit 23. The analysis circuit 24 can receive a test result from the processing circuit 23 and generate failure tendency information 24a according to the test result. The failure tendency information 24a is information indicating a tendency of a failure in the memory 4.

Specifically, the analysis circuit 24 has a bit counter 241 and a holding circuit 242. The bit counter 241 counts the number of failure bits in the memory 4 according to the test result. For example, the bit counter 241 can acquire a comparison result of the comparison circuit 23a and count the number of the bit values “1” indicating the presence of the failure. As a result, the bit counter 241 can count the number of failure bits in the memory 4. The analysis circuit 24 can set a count value of the bit counter 241 as failure bit number information 241a in response to completion of the test performed by the test circuit 27, for example, and output the failure bit number information 241a to the outside via the output terminal AOUT as a part of the failure tendency information 24a.

The holding circuit 242 can extract failure position information from the test result and hold the extracted failure position information. The failure position information is information in which a physical area in the memory 4 is associated with presence or absence of a failure. The failure position information is information indicating hierarchically a physical area in the memory 4. For example, the holding circuit 242 can access the multiple input signature register 23b, acquire and hold a test result compressed and stored in the multiple input signature register 23b as the failure position information 242a. The analysis circuit 24 can output the failure position information 242a held in the holding circuit 242 to the outside as another part of the failure tendency information 24a via the output terminal BOUT in response to completion of the test performed by the test circuit 27, for example.

The failure tendency information 24a is information that can simply indicate an outline of a failure in the memory 4 and can be generated with a small-scale circuit configuration (for example, the bit counter 241 and the holding circuit 242) in the BIST circuit 2 although having a smaller information amount than a failure bit map (FBM). As the failure tendency information 24a output from the output terminals AOUT and BOUT is read, for example, by an information processing apparatus (computer) and displayed on a display of the information processing apparatus, it is possible to perform promptly and roughly yield analysis and failure analysis (analysis of a failure type, a failure occurrence position, and the like) as compared with the case of generating the FBM. As a result, it is possible to shorten time until the start of a countermeasure for identifying a failure occurrence source in a manufacturing process or considering a change of a circuit design.

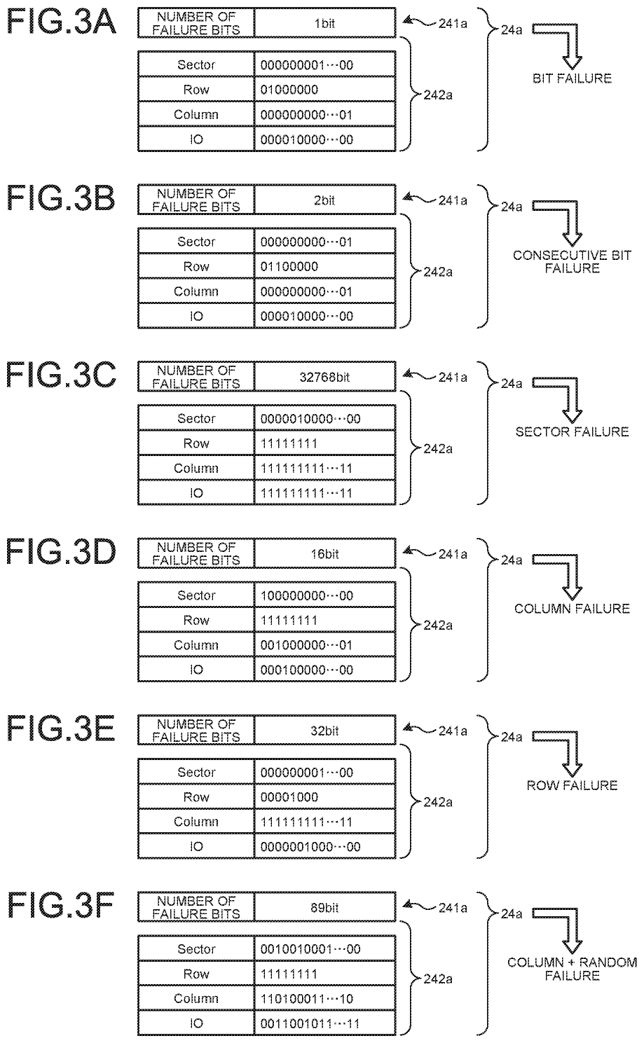

The failure tendency information is, for example, information as illustrated in FIGS. 3A to 3F. FIGS. 3A to 3F are views illustrating a data structure of the failure tendency information.

As illustrated in FIG. 3A, the failure tendency information 24a includes the failure bit number information 241a and the failure position information 242a. The failure bit number information 241a is information indicating the number of failure bits (the number of failure memory cells) in the memory 4. The failure bit number information 241a can be set to, for example, (a bit pattern indicating the number of failure bits)+(a bit pattern in which the number of failure bits is represented in binary notation). As (the bit pattern indicating the number of failure bits) is set in advance to the information processing apparatus that needs to read the failure position information 242a, it is possible to perform failure analysis using the failure bit number information 241a in the information processing apparatus.

The failure position information 242a is information in which a physical area in the memory 4 is associated with presence or absence of a failure. The failure position information 242a can indicate a correspondence between the physical area in the memory 4 and the presence or absence of a failure while hierarchically indicating the physical area in the memory. The failure position information 242a can be set to, for example, (a bit pattern indicating a sector)+(a bit pattern indicating presence or absence of a failure corresponding to the number of sectors)+(a bit pattern indicating a row)+(a bit pattern indicating presence or absence of a failure corresponding to the number of rows in one sector)+(a bit pattern indicating a column)+(a bit pattern indicating presence or absence of a failure corresponding to the number of columns in one I/O)+(a bit pattern indicating an I/O)+(a bit pattern indicating presence or absence of a failure corresponding to the number of I/Os). In the bit pattern indicating the presence or absence of a failure, zero indicates absence of a failure and 1 indicates presence of a failure. For example, as (the bit pattern indicating a sector), (the bit pattern indicating a low), (the bit pattern indicating a column), and (the bit pattern indicating an I/O) are set in advance to the information processing apparatus that needs to read the failure position information 242a, it is possible to perform failure analysis using the failure position information 242a in the information processing apparatus.

The failure position information 242a can be set to, for example, (a bit pattern indicating a start position)+(the bit pattern indicating presence or absence of a failure corresponding to the number of sectors)+(the bit pattern indicating presence or absence of a failure corresponding to the number of rows in one sector)+(the bit pattern indicating presence or absence of a failure corresponding to the number of columns in one I/O)+(the bit pattern indicating presence or absence of a failure corresponding to the number of I/Os). For example, as the number of sectors (for example, 32), the number of rows (for example, 8), the number of columns (for example, 32), and the number of I/Os (for example, 127) are set in advance to the information processing apparatus that needs to read the failure position information 242a, it is possible to perform failure analysis using the failure position information 242a in the information processing apparatus.

For example, the number of failure bits is one bit in the failure tendency information 24a illustrated in FIG. 3A, and the possibility that a failure bit may exist in physical positions of Sector 23, Row 6, Column 0, and IO 123 is illustrated. As such failure tendency information 24a is referred to, it is possible to predict that a type of a failure in the memory 4 is a “bit failure” since there is a possibility that a failure may occur in one bit.

The number of failure bits is two bits in the failure tendency information 24a illustrated in FIG. 3B, and the possibility that a failure bit may exist in physical positions of Sector 0, Rows 5 and 6, Column 0, and IO 123 is illustrated. As such failure tendency information 24a is referred to, it is possible to predict that a type of a failure in the memory 4 is a “consecutive bit failure” since there is a possibility that a failure may occur in consecutive rows (in consecutive bits).

The number of failure bits is 32,768 bits in the failure tendency information 24a illustrated in FIG. 3C, and the possibility that a failure bit may exist in physical positions of Sector 26, Rows 0 to 7, Columns 0 to 31, and IOs 0 to 127 is illustrated. As such failure tendency information 24a is referred to, it is possible to predict that a type of a failure in the memory 4 is a “sector failure” since there is a possibility that a failure may occur in the entire one sector.

The number of failure bits is 16 bits in the failure tendency information 24a illustrated in FIG. 3D, and the possibility that a failure bit may exist in physical positions of Sector 31, Rows 0 to 7, Columns 0 and 29, and IO 124 is illustrated. As such failure tendency information 24a is referred to, it is possible to predict that a type of a failure in the memory 4 is a “column failure” since there is a possibility that a failure may occur in the entire one column.

The number of failure bits is 32 bits in the failure tendency information 24a illustrated in FIG. 3E, and the possibility that a failure bit may exist in physical positions of Sector 23, Row 3, Columns 0 to 31, and IO 121 is illustrated. As such failure tendency information 24a is referred to, it is possible to predict that a type of a failure in the memory 4 is a “row failure” since there is a possibility that a failure may occur in the entire one row.

The number of failure bits is 89 bits in the failure tendency information 24a illustrated in FIG. 3F, and the possibility that a failure bit may exist in physical positions of Sectors 22, 26, and 29, Rows 0 to 7, Columns 1, 23, 24, 28, 30, and 31, and IOs 0, 1, 118, 119, 121, 124, and 125 is illustrated. As such failure tendency information 24a is referred to, it is possible to predict that a type of a failure in the memory 4 is “column failure+random failure” since there are a possibility that a failure may occur in the entire one column and a possibility that a failure may occur in random.

For example, a method of identifying a position of a failure bit (failure memory cell) using a failure bit map (FBM) is also conceivable in a memory test. In such a case, an electric test result for each of a plurality of memory cells in a memory is first detected using a tester, and failure bit information of the detected memory cell is held in a storage device mounted to the tester. Further, the failure bit information is converted into two-dimensional information corresponding to a physical array of the memory cells in the memory. Thereafter, the two-dimensional information is converted into display information for visualization as the FBM on a display device. Here, when a logic tester is used as the tester, there is a possibility of exceeding an information amount of failure bits that can be held in the data storage device mounted to the tester depending on a failure state of a memory to be tested. In such a case, the test needs to be divided into a plurality of times of tests and executed. Thus, it takes a long time until generation of the FBM in the test method of identifying a failure bit position using the FBM so that there is a possibility that a throughput of a test process may decrease.

In the present embodiment, however, it is configured such that a built-in self-test (BIST) circuit 2 is incorporated in the semiconductor device 1, the built-in self-test circuit 2 is used to test the memory 4 in the test process of the semiconductor device 1, and it is possible to generate and output the failure tendency information indicating a tendency of a failure in the memory 4 in the built-in self-test circuit 2. As the failure analysis is performed using this failure tendency information, information for failure analysis can be acquired promptly as compared with the failure analysis performed using the failure bit map (FBM), and thus, it is possible to easily improve the throughput of the test process. Therefore, it is possible to promptly perform yield analysis and failure analysis (analysis of a failure type, a failure occurrence position, and the like) as compared with the case of generating the FBM.

### Modification of Embodiment

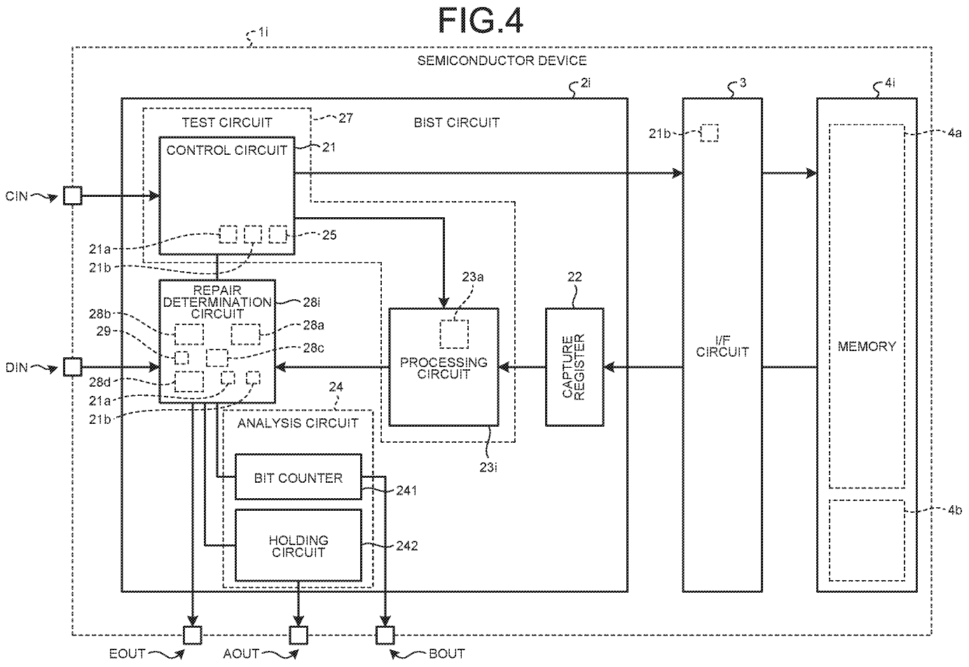

FIG. 4 is a diagram illustrating a configuration of a semiconductor device 1i according to a modification of the embodiment. As illustrated in FIG. 4, a memory 4i may have a redundancy repair area 4b in addition to the memory cell array 4a in the semiconductor device 1i.

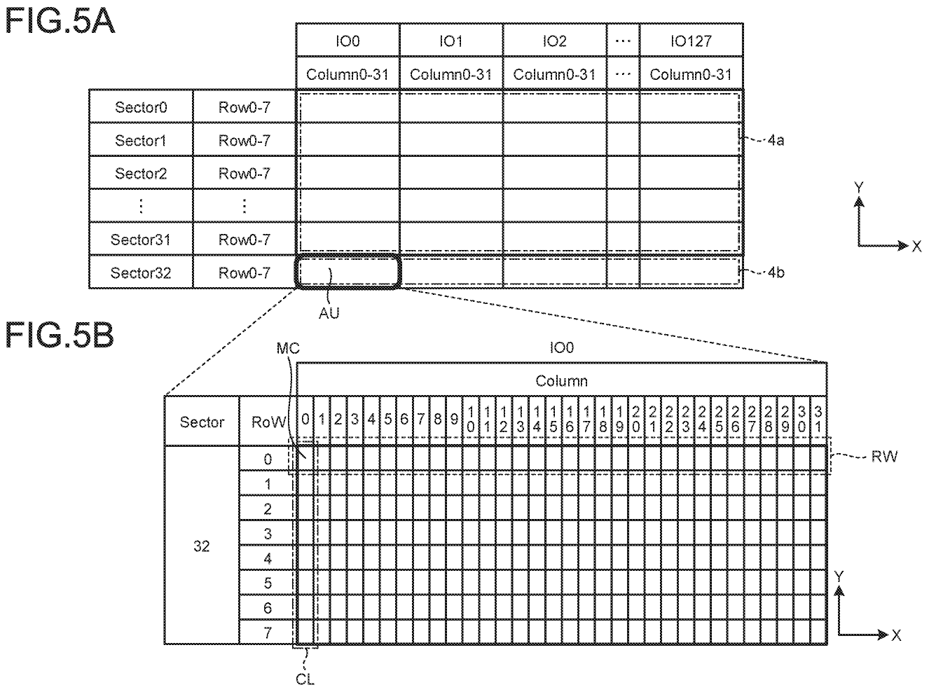

In this case, the BIST circuit 2i may further include a repair determination circuit 28i. The repair determination circuit 28i can acquire and hold management information 29 in advance via an input terminal DIN. With the management information 29, it is possible to hierarchically define physical positions of a two-dimensional array of spare sectors in the redundancy repair area 4b as illustrated in FIGS. 5A and 5B. Further, the management information also includes information on whether a spare sector has already been used for a redundancy repair. FIGS. 5A and 5B are views illustrating a physical configuration of the memory cell array 4a and the redundancy repair area 4b. FIG. 5A is the view illustrating a schematic configuration of the redundancy repair area 4b, and FIG. 5B is the view illustrating a partial configuration of the redundancy repair area 4b in detail.

FIG. 5A illustrates an example regarding a case where an area defined by Sectors 0 to 31 and IOs 0 to 127 is assigned to the memory cell array 4a and an area (eight rows=one sector) defined by Sector 32 and IOs 0 to 127 is assigned to the redundancy repair area 4b in the memory 4i. The redundancy repair area 4b has the array unit AU corresponding to the memory cell array 4a, and spare sectors corresponding to memory cell array MC are arrayed in the array unit AU. For example, when it is determined that a failure is present in the memory cell MC, a sector including this memory cell MC can be assigned using the spare sector and the redundancy repair.

Incidentally, 32 columns=one IO may be assigned as the redundancy repair area 4b.

In addition, the BIST circuit 2i performs a test on the above memory 4i, performs determination on whether the redundancy repair is possible based on a result of the test, and generates failure tendency information based on the test result and a determination result of the redundancy repair.

That is, the multiple input signature register 23b and the address counter 23c are omitted in a processing circuit 23i. The comparison circuit 23a of the processing circuit 23i compares a captured value with a corresponding value in the expected value data 21a, supplies a bit value “0” indicating absence of a failure as a test result to the repair determination circuit 28i if the values coincide with each other, and supplies a bit value “1” indicating presence of a failure as a comparison result to the repair determination circuit 28i if the values do not coincide with each other.

The repair determination circuit 28i includes a determination circuit 28a, a repair result register 28b, a multiple input signature register (MISR) 28c, and an address counter 28d. The address counter 28d counts up a count value whenever the comparison result (test result) is supplied from the processing circuit 23i. The count value of the address counter 23c indicates the order in which captured values have been tested, that is, the one-dimensional logical addresses.

When the test result indicates presence of a failure, the determination circuit 28a uses the count value of the address counter 23c and the address assignment information 21b to identify a physical position of the memory cell MC, and refers to the management information 29 to invert whether the redundancy repair of the memory cell MC is possible. For example, the determination circuit 28a confirms whether or not there is space for a spare sector in the redundancy repair area 4b to determine that the redundancy repair is possible if there is the space and determine that the redundancy repair is impossible if there is no space.

When it is determined that the redundancy repair is possible, the determination circuit 28a stores a repair result in the repair result register 28b. When determining that the redundancy repair is impossible, the determination circuit 28a stores a test result in the multiple input signature register 28c while identifying the physical position of the memory cell MC. At this time, the multiple input signature register 28c stores test results to be distinguished from each other for superordinate physical positions (positions of sectors and positions of IO units) in the hierarchy as illustrated in FIG. 2A from each other, but takes, compresses, stores OR (logical sum) for subordinate physical positions (rows and columns) in the hierarchy.

The bit counter 241 in the analysis circuit 24 counts the number of failure bits corresponding to an area excluding a redundancy-repaired area in the memory 4i based on the test result and the determination result of the redundancy repair. For example, the bit counter 241 can acquire the result of determination that the redundancy repair is impossible, and count the number of results of determination that the redundancy repair is impossible. As a result, the bit counter 241 can count the number of failure bits corresponding to the area excluding the redundancy-repaired area in the memory 4i. The analysis circuit 24 can set a count value of the bit counter 241 as failure bit number information 241a in response to completion of the test performed by the test circuit 27, for example, and output the failure bit number information 241a to the outside via the output terminal AOUT as a part of the failure tendency information 24a.

In addition, the holding circuit 242 extracts and holds failure position information corresponding to the area excluding the redundancy-repaired area in the memory 4i from the test result based on the determination result of the redundancy repair. For example, the holding circuit 242 can access the multiple input signature register 28c, acquire and hold a test result compressed and stored in the multiple input signature register 28c as the failure position information 242a. As a result, the holding circuit 242 can extract and hold the failure position information corresponding to the area excluding the redundancy-repaired area in the memory 4i. The analysis circuit 24 can output the failure position information 242a held in the holding circuit 242 to the outside as another part of the failure tendency information 24a via the output terminal BOUT in response to completion of the test performed by the test circuit 27, for example.

In addition, the repair determination circuit 28i can output repair result information held in the repair result register 28b to the outside via an output terminal EOUT in response to completion of a test performed by the test circuit 27, for example.

In this manner, the modification of the embodiment is configured such that the failure bit (failure memory cell) is redundantly repaired by the spare sector based on the test result in the built-in self-test circuit 2i, and it is possible to generate and output the failure tendency information for a failure bit (failure memory cell) which has not been redundantly repaired in the built-in self-test circuit 2i. Even with such a configuration, information for failure analysis can be acquired promptly by performing the failure analysis using this failure tendency information as compared with the failure analysis performed using the failure bit map (FBM), and thus, it is possible to easily improve the throughput of the test process. In addition, a target for which failure tendency information is to be generated can be limited to the failure bit (failure memory cell) which has not been redundantly repaired, and thus, the throughput of the test process can be easily improved from such a viewpoint.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a memory including a plurality of memory cells;
an interface circuit connected to the memory cell;
a built-in self-test circuit connected to the interface circuit and accessible to the memory via the interface circuit;
wherein the built-in self-test circuit includes:
a test circuit; and
an analysis circuit arranged on an output side of the test circuit and having a bit counter and a holding circuit.

2. The semiconductor device according to claim 1, wherein
the test circuit tests the plurality of memory cells, and
the analysis circuit generates failure tendency information indicating a tendency of a failure in the memory based on a result of the test.

3. The semiconductor device according to claim 2, wherein
the failure tendency information includes
a number of failure bits in the memory and
failure position information in which a physical area in the memory is associated with presence or absence of a failure.

4. The semiconductor device according to claim 3, wherein
the failure position information hierarchically indicates the physical area in the memory.

5. The semiconductor device according to claim 3, wherein
the failure position information includes a sector number, a row number, an IC number, and a column number.

6. The semiconductor device according to claim 4, wherein
the failure position information includes
a sector number indicating a superordinate physical position and
a row number indicating a subordinate physical position.

7. The semiconductor device according to claim 4, wherein
the failure position information includes
an IC number indicating a superordinate physical position and
a column number indicating a subordinate physical position.

8. The semiconductor device according to claim 4, wherein
the failure position information includes a set of a sector number, a row number, an IC number, and a column number.

9. The semiconductor device according to claim 3, wherein
the bit counter counts the number of failure bits based on a result of the test, and
the holding circuit holds the failure position information extracted from the result of the test.

10. The semiconductor device according to claim 4, wherein
the bit counter counts the number of failure bits based on the result of the test, and
the holding circuit holds the failure position information extracted from the result of the test.

11. The semiconductor device according to claim 3, wherein
the analysis circuit outputs a count value of the bit counter as the number of failure bits in response to completion of the test performed by the test circuit and outputs the failure position information held in the holding circuit.

12. The semiconductor device according to claim 1, wherein
the bit counter is electrically connected to the output side of the test circuit, and
the holding circuit is electrically connected to the output side of the test circuit.

13. The semiconductor device according to claim 2, wherein
the bit counter is electrically connected to the output side of the test circuit, and
the holding circuit is electrically connected to the output side of the test circuit.

14. The semiconductor device according to claim 4, wherein
the test circuit stores results of the test to be distinguished from each other for superordinate physical positions in the memory, and stores results of the test by taking and compressing a logical sum for subordinate physical positions in the memory.

15. The semiconductor device according to claim 1, wherein
the built-in self-test circuit further includes a repair determination circuit connected to the output side of the test circuit,
the bit counter is electrically connected to an output side of the repair determination circuit, and
the holding circuit is electrically connected to the output side of the repair determination circuit.

16. The semiconductor device according to claim 2, wherein
the built-in self-test circuit further includes a repair determination circuit connected to the output side of the test circuit,
the bit counter is electrically connected to an output side of the repair determination circuit, and
the holding circuit is electrically connected to the output side of the repair determination circuit.

17. The semiconductor device according to claim 15, wherein
the memory further includes a spare sector,
the repair determination circuit determines whether a redundancy repair is possible using the spare sector based on a result of the test,
the bit counter counts a number of failure bits corresponding to an area excluding a redundantly repaired area in the memory based on the result of the test and a determination result of the redundancy repair, and
the holding circuit holds failure position information in which a physical area in the memory is associated with presence or absence of a failure and which is extracted to correspond to the area excluding the redundantly repaired area in the memory from the result of the test based on the determination result of the redundancy repair.

18. The semiconductor device according to claim 16, wherein
the memory further includes a spare sector,
the repair determination circuit determines whether a redundancy repair is possible using the spare sector based on a result of the test,
the bit counter counts a number of failure bits corresponding to an area excluding a redundantly repaired area in the memory based on the result of the test and a determination result of the redundancy repair, and
the holding circuit holds failure position information in which a physical area in the memory is associated with presence or absence of a failure and which is extracted to correspond to the area excluding the redundantly repaired area in the memory from the result of the test based on the determination result of the redundancy repair.

19. The semiconductor device according to claim 17, wherein
the failure position information hierarchically indicates a physical area in the memory, and
the repair determination circuit stores results of the test to be distinguished from each other for superordinate physical positions in the memory, and stores results of the test by taking and compressing a logical sum for subordinate physical positions in the memory.

20. The semiconductor device according to claim 18, wherein
the failure position information hierarchically indicates a physical area in the memory, and
the repair determination circuit stores results of the test to be distinguished from each other for superordinate physical positions in the memory, and stores results of the test by taking and compressing a logical sum for subordinate physical positions in the memory.
